(19) United States
(12) Patent Application Publication
(10) Pub. No.: US 2026/0304777 A1
(43) Pub. Date: Oct. 1, 2026

(54) SEMICONDUCTOR STRUCTURE

(71) Applicant: MACRONIX International Co., Ltd., Hsinchu (TW)

(72) Inventors: Yung-Hsiang Chen, Taipei City (TW); I-Chen Yang, Miaoli County (TW); Yao-Wen Chang, Hsinchu County (TW); Jung-Chuan Ting, Hsinchu County (TW)

(73) Assignee: MACRONIX International Co., Ltd., Hsinchu (TW)

(21) Appl. No.: 19/090,394

(22) Filed: Mar. 26, 2025

(51) Int. Cl. H10B 43/40; H10B 41/10; H10B 41/41; H10B 43/10

(52) U.S. Cl. CPC H10B 43/40; H10B 41/10; H10B 41/41; H10B 43/10

(57) ABSTRACT

The present disclosure provides a semiconductor structure. The semiconductor structure may be included in a memory device. The memory device is, for example, a 3D NAND flash memory and provides a storage media with high-performance and high-capacity. The semiconductor structure includes a substrate including an active region and a source region, a drain region and at least one lightly doped region disposed in the active region, a gate layer disposed over the active region, and a dummy gate layer disposed over the lightly doped region and electrically connected to the gate layer. The source region and the drain region are disposed at opposite sides of the gate layer in a first direction, and the lightly doped region is configured between the gate layer and the drain region.

### BACKGROUND

### Technical Field

The present disclosure relates to a semiconductor structure, and in particular, to a semiconductor structure for high voltage semiconductor components.

### Description of Related Art

The High voltage semiconductor components are power components commonly applied in analog and/or digital circuits, which may be classified into planar power semiconductor components and vertical power semiconductor components according to the direction of the current flow. In planar power semiconductor components, increasing the distance from the gate to the drain is one of techniques to improve the operating voltage of the power semiconductor component. However, this technique will encounter issues coming from the increased distance between the gate and the drain. For example, as the distance from the gate to the drain increases, the drive voltage (Ion) of the power semiconductor component will also be affected due to the increase in resistance, and the techniques to reduce resistance, such as increasing the doping concentration of the lightly doped region, may result to a decrease in the breakdown voltage of the power semiconductor component, affecting the operating voltage of the power semiconductor component.

Therefore, there is a continuous need for those skilled in the art to improve to improve the high voltage semiconductor components.

### SUMMARY

The present disclosure provides a semiconductor structure in which a dummy gate layer is configured over a lightly doped region and being electrically connected to a gate layer, which is beneficial for enhancing the breakdown voltage and avoids influences on the drive voltage of the high voltage semiconductor component including the semiconductor structure.

An embodiment of the present disclosure provides a semiconductor structure including a substrate, a gate layer, and a dummy gate layer. The substrate includes an active region and a source region, a drain region, and at least one lightly doped region that are disposed in the active region. The gate layer is disposed over the active region, wherein the source region and the drain region are configured at opposite sides of the gate layer in a first direction, and the lightly doped region are configured between the gate layer and the drain region. The dummy gate layer is disposed over the lightly doped region and is electrically connected to the gate layer.

Another embodiment of the present disclosure provides a semiconductor structure including a substrate, a gate layer, and a plurality of dummy gate layers. The substrate includes an active region and a first source/drain region, a second source/drain region, and a plurality of lightly doped regions that are disposed in the active region. The gate layer is disposed over the active region, wherein the first source/drain region and the second source/drain region are configured at opposite sides of the gate layer in a first direction, and the plurality of lightly doped regions are configured between the gate layer and the first source/drain region, and between the gate layer and the second source/drain region, respectively. The plurality of dummy gate layers are disposed over the plurality of lightly doped regions of the substrate, respectively, and are electrically connected to the gate layer.

Yet another embodiment of the present disclosure provides a semiconductor structure including a substrate, a gate structure, and a dummy gate structure. The substrate includes an active region and a source region, a drain region, and at least one lightly doped region that are disposed in the active region, wherein the lightly doped region is disposed between the source region and the drain region in a first direction. The gate structure is disposed on the active region and includes a gate layer and a gate insulation layer between the gate layer and the substrate, wherein the source region and the drain region are configured at opposite sides of the gate layer in the first direction, and the lightly doped region is configured between the gate layer and the drain region. The dummy gate structure is disposed on the lightly doped region and includes a dummy gate layer and a dummy gate insulation layer between the dummy gate layer and the substrate, wherein the dummy gate layer is electrically connected to the gate layer.

Based on the above, in the semiconductor structure of the present disclosure, the dummy gate layer is configured to be over a lightly doped region and electrically connected to the gate layer, so that the impact on the breakdown voltage can be reduced while the doping concentration of the lightly doped region is increased, and therefore the high-voltage semiconductor component including the semiconductor structure can have desired driving voltage and breakdown voltage at the same time.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A illustrates a schematic three-dimensional structural diagram of a memory block in a memory device according to an embodiment of the present disclosure.

FIG. 1B illustrates a partial structural schematic diagram of a memory block according to an embodiment of the present disclosure.

FIG. 2A illustrates a schematic top view of a semiconductor structure according to a first embodiment of the present disclosure.

FIG. 2B illustrates a schematic cross-sectional view taken along line A-A′ of FIG. 2A according to an embodiment of the present disclosure.

FIG. 3 illustrates a schematic top view of a semiconductor structure according to a second embodiment of the present disclosure.

FIG. 4 illustrates a schematic top view of a semiconductor structure according to a third embodiment of the present disclosure.

FIG. 5 illustrates a schematic top view of a semiconductor structure according to a fourth embodiment of the present disclosure.

FIG. 6 illustrates a schematic top view of a semiconductor structure according to a fifth embodiment of the present disclosure.

FIG. 7A illustrates a schematic top view of a semiconductor structure according to a sixth embodiment of the present disclosure.

FIG. 7B illustrates a schematic cross-sectional view taken along line A-A′ of FIG. 7A according to an embodiment of the present disclosure.

FIG. 7C illustrates a schematic cross-sectional view taken along line A-A′ of FIG. 7A according to another embodiment of the present disclosure.

FIG. 8A illustrates a three-dimensional schematic diagram of a semiconductor structure according to a seventh embodiment of the present disclosure.

FIG. 8B illustrates a schematic cross-sectional view taken along line B-B′ of FIG. 8A according to an embodiment of the present disclosure.

FIG. 9A illustrates a three-dimensional schematic diagram of a semiconductor structure according to an eighth embodiment of the present disclosure.

FIG. 9B illustrates a schematic cross-sectional view taken along line C-C′ of FIG. 9A according to an embodiment of the present disclosure.

### DESCRIPTION OF THE EMBODIMENTS

Reference is made to the figures of this embodiment to more comprehensively elucidate the present invention. However, the present invention may be embodied in various different forms and should not be limited to the embodiments described herein. The thicknesses of layers and regions in the figures are exaggerated for clarity. The same or similar reference numbers indicate the same or similar components, which will not be redundantly described in the following paragraphs.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

The semiconductor structure may be, for example, included in a memory device. The memory device of the present disclosure may be, for example, a three-dimensional NAND flash memory, which is characterized by high performance and high capacity.

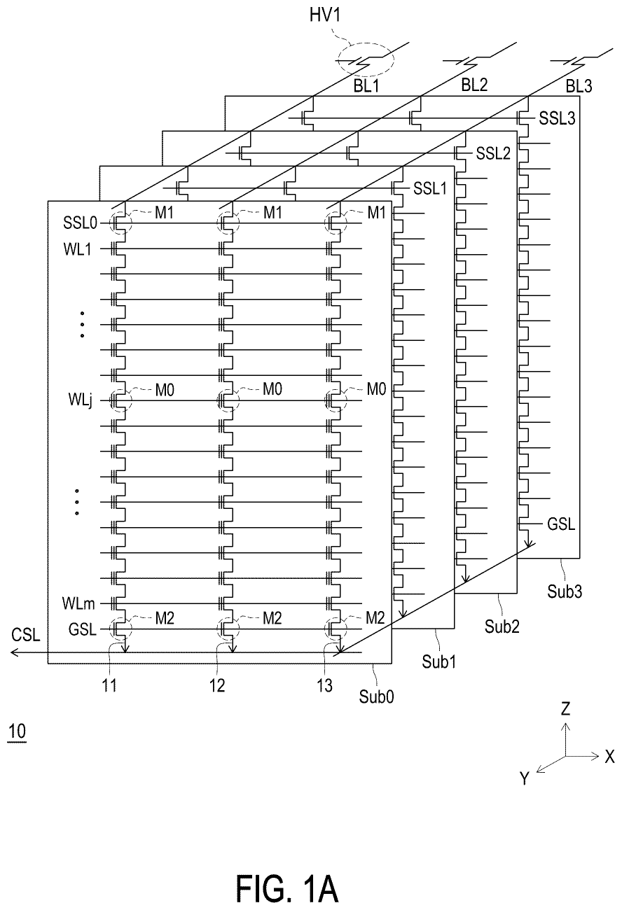

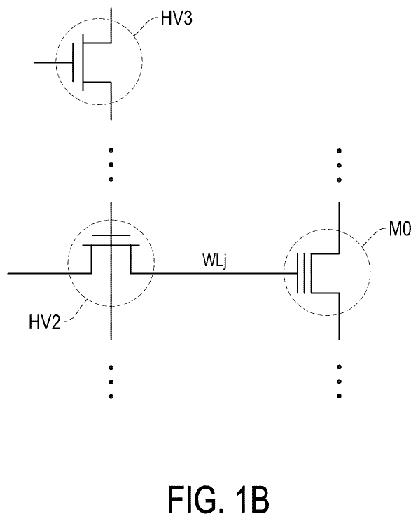

Please refer to FIG. 1A and FIG. 1B in which FIG. 1A shows the equivalent circuit of the block 10 of the memory device in a three-dimensional manner, and FIG. 1B shows the equivalent circuit of memory cells M0 in the block 10 according to an embodiment of the present disclosure. The memory cells M0 in FIG. 1A are configured in the XYZ three-dimensional coordinate system of the block 10, but the present disclosure is not limited thereto. In this example, the block 10 may be divided into four sub-blocks Sub0 to Sub3, and each sub-block Sub0 to Sub3 may control operations independently.

Taking sub-block Sub0 as an example, in FIG. 1A, each string 11, 12, 13 includes a plurality of memory cells M0 connected in series along the Z direction. Each memory cell M0 on each string 11, 12, 13 corresponds to one word line WLj of the word lines WL1 to WLm. The word line WLj may be a word line layer in the XY plane. In this embodiment, j is any positive integer greater than or equal to 1 and less than or equal to m. The memory cell M1 may be configured as a string selection transistor coupled to the string selection line SSL0, and the memory cell M2 may be configured as a ground selection transistor coupled to the ground selection line GSL. The string selection transistor and the ground selection transistor are respectively arranged on opposite sides of the plurality of memory cells M0 on each string 11, 12, 13. In this example, the strings 11, 12 and 13 coupled on the same plane (e.g., the plane defined by the X direction and the Z direction) of the same string selection line SSL0 may be defined as the sub-block Sub0.

Strings 11, 12 and 13 are respectively connected to bit lines BL1, BL2 and BL3 through corresponding string selection transistors on the string selection line SSL0. In different sub-blocks, strings of the same columns are connected to the same bit lines in the Y direction. The string selection line SSL0 may be a conductor or layer formed over the top of topmost word line WL1. Each string 11, 12, 13 may be connected to the same common source line CSL through a corresponding ground selection transistor on the ground selection line GSL. The ground selection line GSL may be a conductor or layer formed under the bottom of the bottommost word line WLm. The common source line CSL may be a conductive layer formed over the substrate of the memory device.

In the block 10, the string selection line SSL0 of the sub-block Sub0, the string selection line SSL1 of the sub-block Sub1, the string selection line SSL2 of the sub-block Sub2, and the string selection line SSL3 of the sub-block Sub3 may be located on the same conductive layer, but separated into separate stripes. Each separate stripe on the same conductive layer may independently control the operation of a corresponding sub-block within the block 10.

In some embodiments, the memory cell M0 coupled to the same word line WLj or word line layer in the sub-block Sub0 may be defined as a page (in a single level cell (SLC) mode) or three pages (in a triple level cell (TLC) mode). In TLC mode, the three pages include high page, middle page, and low page. The same voltage is applied to the memory cell M0 on the same word line WLj. Each word line WLj may be connected to a driver circuit, such as an X decoder (or a scan driver).

In some embodiments, within the sub-block Sub0, one or more dummy lines or layers (not shown) are provided between the string selection line SSL0 and the corresponding topmost word line WL1 and/or are provided between the ground selection line GSL and the bottommost word line WLm. In another embodiment, one or more dummy lines or layers (not shown) are provided in the middle portion of the strings 11, 12, 13 within the sub-block Sub0.

In some embodiments, as shown in FIG. 1A, the bit lines BL1, BL2 and BL3 may be connected to high voltage semiconductor components HV1 to block erase bias from entering the sense amplifiers (not shown). In some embodiments, as shown in FIG. 1B, the word line WLj corresponding to the memory cell M0 may be connected to a high voltage semiconductor component HV2 to transmit program bias. In some embodiments, the high voltage semiconductor component HV2 may be a pass transistor. In some embodiments, the pre-charge transistor used to activate the pass transistor may also be a high voltage component (e.g., the high voltage semiconductor component HV3 shown in FIG. 1B).

The semiconductor structure of the present disclosure will be described below. In some embodiments, the semiconductor structure of the present disclosure may be applied to at least one of the high voltage semiconductor components HV1, HV2 and HV3.

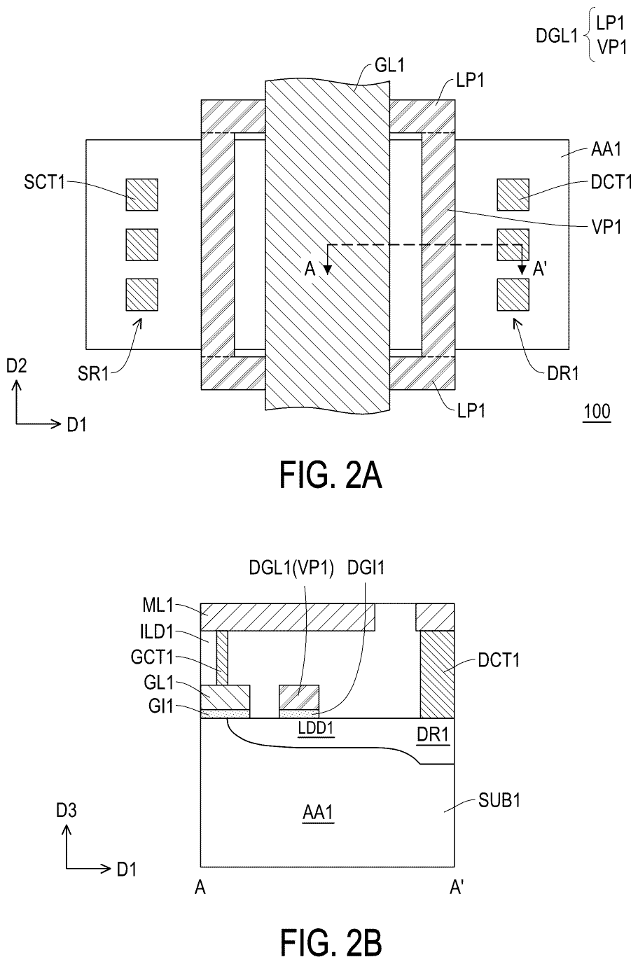

FIG. 2A illustrates a schematic top view of a semiconductor structure according to a first embodiment of the present disclosure. FIG. 2B illustrates a schematic cross-sectional view taken along line A-A′ of FIG. 2A according to an embodiment of the present disclosure. For the convenience of explanation, FIG. 2A only shows a schematic top view of the active region AA1, source region SR1, drain region DR1, gate layer GL1, dummy gate layer DGL1, drain conductive contact DCT1, and source conductive contact SCT1 to clearly understand the corresponding relationships between respective elements.

Referring to FIG. 2A and FIG. 2B, the semiconductor structure 100 includes a substrate SUB1, a gate layer GL1, and a dummy gate layer DGL1.

The substrate SUB1 includes an active region AA1 and a source region SR1, a drain region DR1, and at least one lightly doped region LDD1 that are disposed in the active region AA1. The substrate SUB1 may include a semiconductor substrate or a semiconductor-on-insulator (SOI) substrate. The semiconductor material in the semiconductor substrate or the SOI substrate may include elemental semiconductors such as Si or Ge), alloy semiconductors such as SiGe, or compound semiconductors such as III-V group semiconductors. The semiconductor material may be doped with a P-type dopant or a N-type dopant to give the substrate SUB1 a P-type or N-type conductivity.

The gate layer GL1 is disposed over the active region AA1. The source region SR1 and the drain region DR1 are configured at opposite sides of the gate layer GL1 in the first direction D1, and the at least one lightly doped region LDD1 is configured between the gate layer GL1 and the drain region DR1. The gate layer GL1 may include conductive materials suitable for the gates, such as polysilicon. In this embodiment, the at least one lightly doped region LDD1 may be configured to be plural and being respectively between the gate layer GL1 and the drain region DR1, and between the gate layer GL1 and the source region SR1.

The dummy gate layer DGL1 is disposed over the lightly doped region LDD1 and is electrically connected to the gate layer GL1, so that the impact on the breakdown voltage can be reduced while the doping concentration of the lightly doped region LDD1 is increased, and therefore the high-voltage semiconductor component (such as the high voltage semiconductor component HV1 in FIG. 1A or the high voltage semiconductor component HV2 or HV3 shown in FIG. 1B) including the semiconductor structure 100 can have desired driving voltage and breakdown voltage at the same time. The dummy gate layer DGL1 may include conductive materials, such as polysilicon. In some embodiments, the dummy gate layer DGL1 may be formed simultaneously with the gate layer GL1 in the same process. In other words, the dummy gate layer DGL1 and the gate layer GL1 may be made of the same material.

In this embodiment, as shown in FIG. 2A, the dummy gate layer DGL1 may be electrically connected to the gate layer GL1 by directly contacting the gate layer GL1. In this embodiment, the dummy gate layer DGL1 may include a first portion LP1 extending in the first direction D1 and a second portion VP1 extending in a second direction D2 different from the first direction D1. In some embodiments, the first direction D1 may be perpendicular to the second direction D2. The second portion VP1 may extend across the active region AA1 and contact the gate layer GL1 through the first portion LP1. In this embodiment, the first portion LP1 may be disposed outside the active region AA1, so that the influence on the lightly doped region LDD1 caused by the first portion LP1 of the dummy gate layer DGL1 can be reduced during the formation of the lightly doped region LDD1.

In this embodiment, the dummy gate layer DGL1 may include a plurality of first portions LP1 disposed at opposite ends of the second portion VP1 in the second direction D2.

In some embodiments, the semiconductor structure 100 may include a gate insulation layer GI1 disposed between the gate layer GL1 and the substrate SUB1, and a dummy gate insulation layer DGI1 disposed between the dummy gate layer DGL1 and the substrate SUB1. The gate insulation layer GI1 may include any material such as oxide (e.g., silicon oxide) suitable for the gate dielectric layer. The dummy gate insulation layer DGI1 may include any suitable insulation material. In some embodiments, the gate insulation layer GI1 may be formed simultaneously with the dummy gate insulation layer DGI1 in the same process. In other words, the gate insulation layer GI1 and the dummy gate insulation layer DGI1 may be made of the same material.

In some embodiments, the semiconductor structure 100 may include a dielectric layer IL1 disposed on the substrate SUB1 and covering the gate layer GL1 and the dummy gate layer DGL1. The dielectric layer IL1 may include any suitable dielectric material such as oxide (e.g., silicon oxide).

In some embodiments, the semiconductor structure 100 may include a drain conductive contact DCT1 disposed on the drain region DR1 and electrically connected to the drain region DR1, a source conductive contact SCT1 disposed on the source region SR1 and electrically connected to the source region SR1, and a gate conductive contact GCT1 disposed on the gate layer GL1 and electrically connected to the gate layer GL1. The drain conductive contact DCT1, the source conductive contact SCT1, and the gate conductive contact GCT1 may be disposed or embedded in the dielectric layer IL1 and may each include suitable conductive materials such as metals or metal alloys. The metals and metal alloys may be, for example, Cu, Al, Ti, Ta, W, Pt, Cr, Mo, or alloys thereof. In this embodiment, the dummy gate layer DGL1 may be disposed between the gate layer GL1 and the drain conductive contact DCT1, and between the gate layer GL1 and the source conductive contact SCT1.

In some embodiments, the semiconductor structure 100 may include a wiring layer ML1 disposed on the dielectric layer IL1. The wiring layer ML1 may include wirings electrically connected to the gate layer GL1 and wirings respectively electrically connected to the drain conductive contact DCT1 and the source conductive contact SCT1. The wiring layer ML1 may include suitable conductive materials such as metals or metal alloys. The metals and metal alloys may be, for example, Cu, Al, Ti, Ta, W, Pt, Cr, Mo, or alloys thereof.

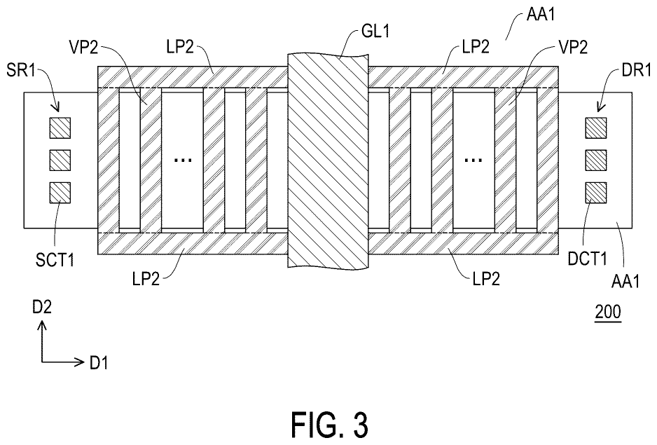

FIG. 3 illustrates a schematic top view of a semiconductor structure according to a second embodiment of the present disclosure. The semiconductor structure 200 shown in FIG. 3 is similar to the semiconductor structure 100 shown in FIG. 2A. The main difference therebetween is relied on that the dummy gate layer DGL2 of the semiconductor structure 200 is different from the dummy gate layer DGL1 of the semiconductor structure 100. Other identical or similar elements are represented by the same or similar reference numerals, and will not be repeated hereinafter.

Referring to FIG. 3, the dummy gate layer DGL2 of the semiconductor structure 200 may include a first portion LP2 extending in the first direction D1 and a second portion VP2 extending across over the active region AA1 in the second direction D2. In this embodiment, the dummy gate layer DGL2 may include a plurality of second portions VP2 arranged in the first direction D1, wherein each second portion VP2 is in contact with the gate layer GL1 through the first portion LP1 to be electrically connected to the gate layer GL1. This configuration may be beneficial for adjusting the electric potential distribution in the lightly doped region LDD1, and therefore the impact on the breakdown voltage can be reduced while the doping concentration of the lightly doped region LDD1 is increased. As such, the high-voltage semiconductor component (such as the high voltage semiconductor component HV1 in FIG. 1A or the high voltage semiconductor component HV2 or HV3 shown in FIG. 1B) including the semiconductor structure 200 can have desired driving voltage and breakdown voltage at the same time.

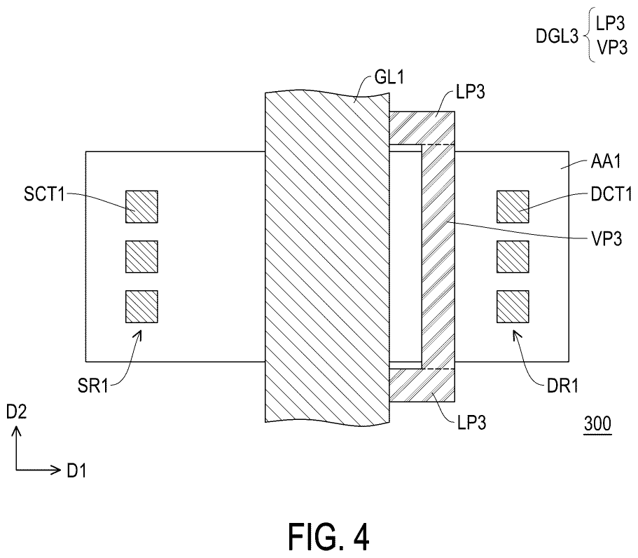

FIG. 4 illustrates a schematic top view of a semiconductor structure according to a third embodiment of the present disclosure. The semiconductor structure 300 shown in FIG. 4 is similar to the semiconductor structure 100 shown in FIG. 2A. The main difference therebetween is relied on that the dummy gate layer DGL3 of the semiconductor structure 300 is different from the dummy gate layer DGL1 of the semiconductor structure 100. Other identical or similar elements are represented by the same or similar reference numerals, and will not be repeated hereinafter.

Referring to FIG. 4, the dummy gate layer DGL3 of the semiconductor structure 300 may include a first portion LP3 extending in the first direction D1 and a second portion VP3 extending across over the active region AA1 in the second direction D2. In this embodiment, the dummy gate layer DGL3 may be disposed only between the gate layer GL1 and the drain conductive contact DCT1, which may be beneficial for reducing the horizontal area of the semiconductor structure 300.

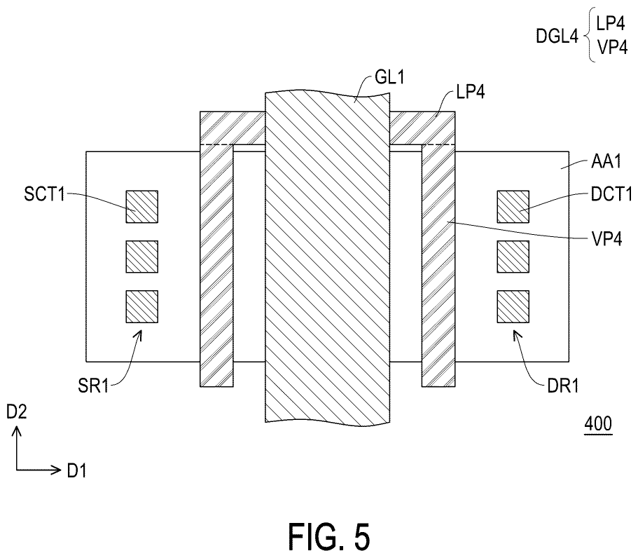

FIG. 5 illustrates a schematic top view of a semiconductor structure according to a fourth embodiment of the present disclosure. The semiconductor structure 400 shown in FIG. 5 is similar to the semiconductor structure 100 shown in FIG. 2A. The main difference therebetween is relied on that the dummy gate layer DGL4 of the semiconductor structure 400 is different from the dummy gate layer DGL1 of the semiconductor structure 100. Other identical or similar elements are represented by the same or similar reference numerals, and will not be repeated hereinafter.

Referring to FIG. 5, the dummy gate layer DGL4 of the semiconductor structure 400 may include a first portion LP4 extending in the first direction D1 and a second portion VP4 extending across over the active region AA1 in the second direction D2. In this embodiment, the first portion LP4 of the dummy gate layer DGL4 may be disposed only at one end of the two opposite ends of the second portion VP4 in the second direction D2.

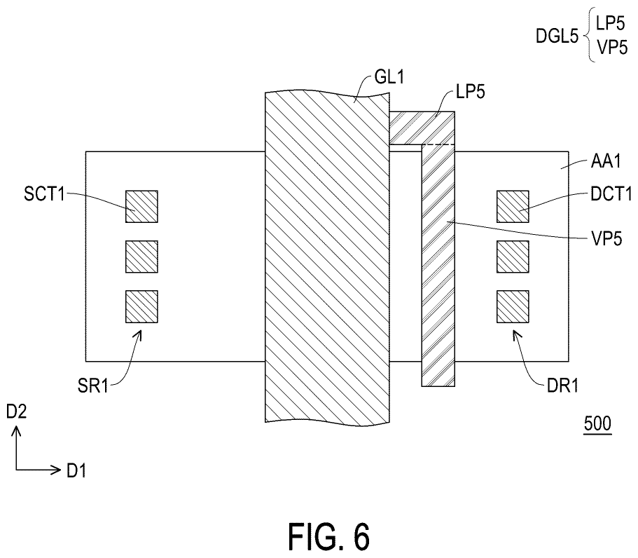

FIG. 6 illustrates a schematic top view of a semiconductor structure according to a fifth embodiment of the present disclosure. The semiconductor structure 500 shown in FIG. 6 is similar to the semiconductor structure 300 shown in FIG. 4. The main difference therebetween is relied on that the dummy gate layer DGL5 of the semiconductor structure 500 is different from the dummy gate layer DGL3 of the semiconductor structure 300. Other identical or similar elements are represented by the same or similar reference numerals, and will not be repeated hereinafter.

Referring to FIG. 6, the dummy gate layer DGL5 of the semiconductor structure 500 may include a first portion LP5 extending in the first direction D1 and a second portion VP5 extending across over the active region AA1 in the second direction D2. In this embodiment, the first portion LP5 of the dummy gate layer DGL5 may be disposed only at one end of the two opposite ends of the second portion VP5 in the second direction D2.

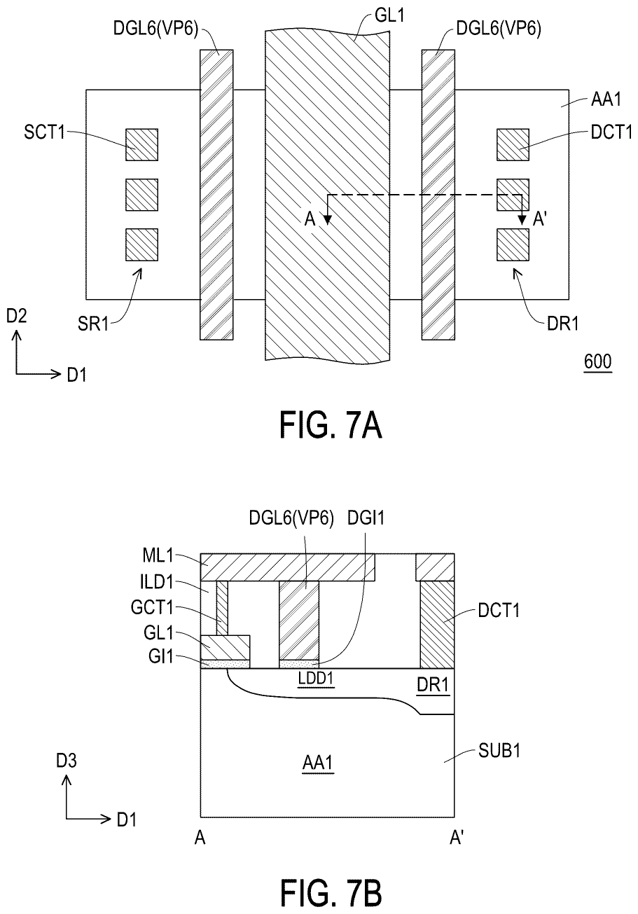

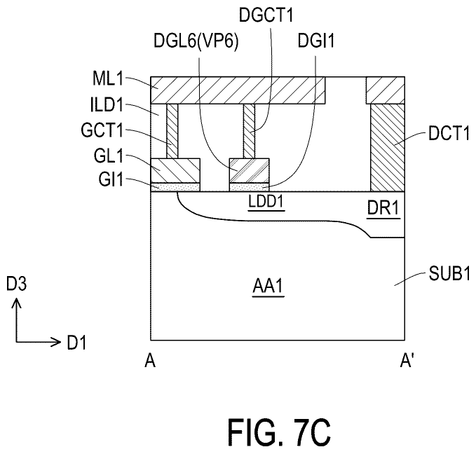

FIG. 7A illustrates a schematic top view of a semiconductor structure according to a sixth embodiment of the present disclosure. FIG. 7B illustrates a schematic cross-sectional view taken along line A-A′ of FIG. 7A according to an embodiment of the present disclosure. FIG. 7C illustrates a schematic cross-sectional view taken along line A-A′ of FIG. 7A according to another embodiment of the present disclosure. The semiconductor structure 600 shown in FIG. 7A is similar to the semiconductor structure 100 shown in FIG. 2A. The main difference therebetween is relied on that the dummy gate layer DGL6 of the semiconductor structure 600 is different from the dummy gate layer DGL1 of the semiconductor structure 100. Other identical or similar elements are represented by the same or similar reference numerals, and will not be repeated hereinafter.

Referring to FIG. 7A, the dummy gate layer DGL6 of the semiconductor structure 600 may only include a second portion VP6 extending across over the active region AA1 in the second direction D2. In other words, the dummy gate layer DGL6 may be spaced apart from the gate layer GL1 in the first direction D1. In this embodiment, the wiring layer ML1 may be disposed over the gate layer GL1, and the dummy gate layer DGL6 may be electrically connected to the gate layer GL1 through the wiring layer ML1. In some embodiments, as shown in FIG. 7B, the top surface of the dummy gate layer DGL6 may be directly in contact with the wiring layer ML1. In other embodiments, as shown in FIG. 7C, the semiconductor structure 600 may include a conductive contact DGCT1 disposed on the dummy gate layer DGL6 and electrically connecting the dummy gate layer DGL6 to the wiring layer ML1. The conductive contact DGCT1 may be disposed or embedded in the dielectric layer IL1 and may include suitable conductive materials such as metals or metal alloys. The metals and metal alloys may be, for example, Cu, Al, Ti, Ta, W, Pt, Cr, Mo, or alloys thereof.

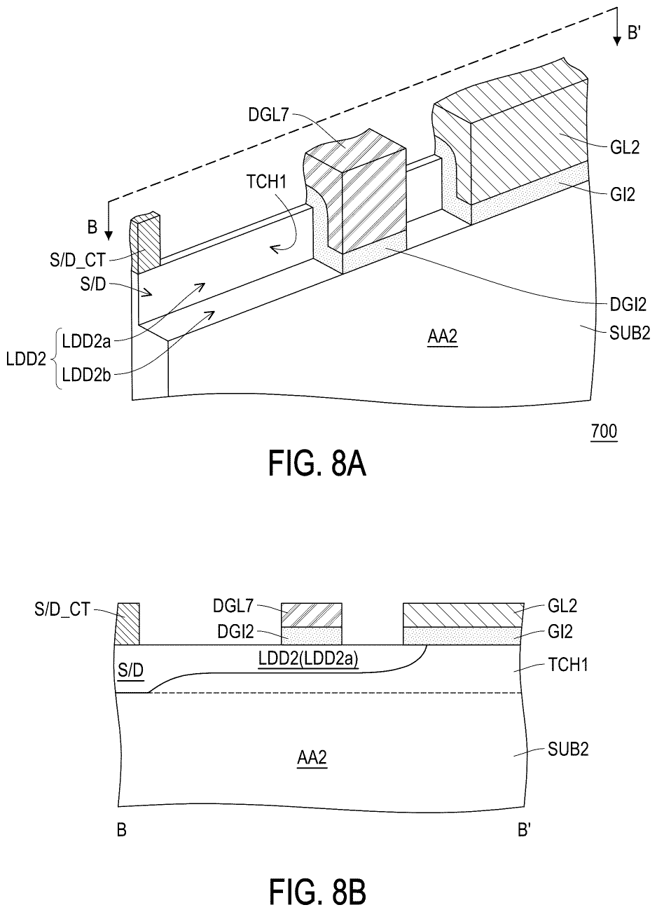

FIG. 8A illustrates a three-dimensional schematic diagram of a semiconductor structure according to a seventh embodiment of the present disclosure. FIG. 8B illustrates a schematic cross-sectional view taken along line B-B′ of FIG. 8A according to an embodiment of the present disclosure. The semiconductor structure 700 shown in FIG. 8A is similar to the semiconductor structure 100 shown in FIG. 2A. The main difference therebetween is relied on that the substrate SUB2 of the semiconductor structure 700 is different from the substrate SUB1 of the semiconductor structure 100, so that the lightly doped region LDD2 formed in the active region AA2 of the substrate SUB2 and the gate insulation layer GI2, dummy gate insulation layer DGI2, gate layer GL2, and dummy gate layer DGL7 that are formed on the substrate SUB2 are different from the lightly doped region LDD1 formed in the active region AA1 of the substrate SUB1 and the gate insulation layer GI1, dummy gate insulation layer DGI1, gate layer GL1, and dummy gate layer DGL1 that are formed on the substrate SUB1 of the semiconductor structure 100. Other identical or similar elements are represented by the same or similar reference numerals, and will not be repeated hereinafter.

Referring to FIG. 8A, the substrate SUB2 may include a trench TCH1 where an active region AA2 is formed therein, wherein the gate layer GL2 and the dummy gate layer DGL7 may each include a portion covering a bottom surface and a sidewall of the trench TCH1. The gate insulation layer GI2 may be disposed between the gate layer GL2 and the substrate SUB2, and the d ummy gate insulation layer DGI2 may be disposed between the dummy gate layer DGL7 and the substrate SUB2. In this embodiment, the active region AA2 may include a source/drain region S/D and a lightly doped region LDD2 disposed between the source/drain region S/D and the gate layer GL2. The source/drain region S/D shown in FIG. 8A may be electrically connected to a conductive contact S/D_CT, wherein the source/drain region S/D may be corresponded to the source region SR1 or the drain region DR1 shown in FIG. 2A, and the conductive contact S/D_CT may be corresponded to the source conductive contact SCT1 or the drain conductive contact DCT1 shown in FIG. 2A. In this embodiment, the lightly doped region LDD2 may include a side portion LDD2a formed in the sidewall of the trench TCH1 and a bottom portion LDD2b formed in the bottom surface of the trench TCH1.

In this embodiment, the dummy gate layer DGL7 may be disposed over the lightly doped region LDD2 and electrically connected to the gate layer GL2, so that the impact on the breakdown voltage can be reduced while the doping concentration of the lightly doped region LDD2 is increased, and therefore the high-voltage semiconductor component (such as the high voltage semiconductor component HV1 in FIG. 1A or the high voltage semiconductor component HV2 or HV3 shown in FIG. 1B) including the semiconductor structure 700 can have desired driving voltage and breakdown voltage at the same time. In other words, the semiconductor structure 700 may be applied in semiconductor devices with a trench architecture as well.

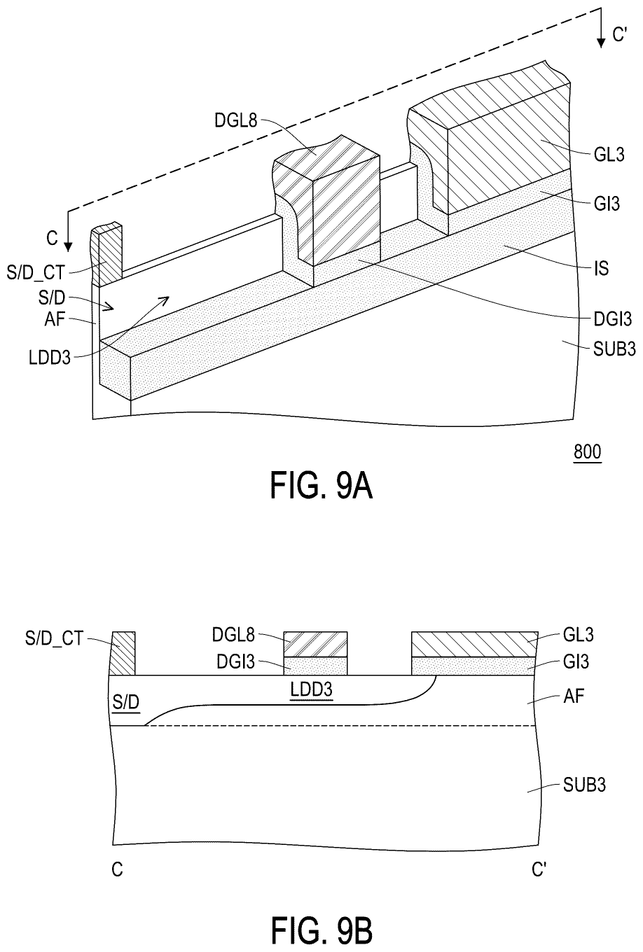

FIG. 9A illustrates a three-dimensional schematic diagram of a semiconductor structure according to an eighth embodiment of the present disclosure. FIG. 9B illustrates a schematic cross-sectional view taken along line C-C′ of FIG. 9A according to an embodiment of the present disclosure. The semiconductor structure 800 shown in FIG. 9A is similar to the semiconductor structure 100 shown in FIG. 2A. The main difference therebetween is relied on that the substrate SUB3 of the semiconductor structure 800 is different from the substrate SUB1 of the semiconductor structure 100, so that the lightly doped region LDD3 formed in an active fin AF of the substrate SUB3 and the gate insulation layer GI3, dummy gate insulation layer DGI3, gate layer GL3, and dummy gate layer DGL8 that are formed on the substrate SUB3 are different from the lightly doped region LDD1 formed in the active region AA1 of the substrate SUB1 and the gate insulation layer GI1, dummy gate insulation layer DGI1, gate layer GL1, and dummy gate layer DGL1 that are formed on the substrate SUB1 of the semiconductor structure 100. Other identical or similar elements are represented by the same or similar reference numerals, and will not be repeated hereinafter.

Referring to FIG. 9A, the substrate SUB3 may include an active fin AF, protruding from a top surface of the substrate SUB3, where the active region is formed therein. The gate layer GL3 and the dummy gate layer DGL8 may each include a portion covering a top surface and sidewalls of the active fin AF. The gate insulation layer GI3 may be disposed between the gate layer GL3 and the substrate SUB3, and the dummy gate insulation layer DGI3 may be disposed between the dummy gate layer DGL8 and the substrate SUB3. In this embodiment, the active fin AF may include a source/drain region S/D and a lightly doped region LDD3 disposed between the source/drain region S/D and the gate layer GL3. The source/drain region S/D shown in FIG. 9A may be electrically connected to the conductive contact S/D_CT, wherein the source/drain region S/D may be corresponded to the source region SR1 or the drain region DR1 shown in FIG. 2A, and the conductive contact S/D_CT may be corresponded to the source conductive contact SCT1 or the drain conductive contact DCT1 shown in FIG. 2A. In this embodiment, the lightly doped region LDD3 may be formed in the active fin AF. In some embodiments, the semiconductor structure 800 may include an isolation structure IS formed on the substrate SUB3. The isolation structure IS may include any suitable insulation materials such as oxide (e.g., silicon oxide).

In this embodiment, the dummy gate layer DGL8 may be disposed over the lightly doped region LDD3 and electrically connected to the gate layer GL3, so that the impact on the breakdown voltage can be reduced while the doping concentration of the lightly doped region LDD3 is increased, and therefore the high-voltage semiconductor component (such as the high voltage semiconductor component HV1 in FIG. 1A or the high voltage semiconductor component HV2 or HV3 shown in FIG. 1B) including the semiconductor structure 800 can have desired driving voltage and breakdown voltage at the same time. In other words, the semiconductor structure 800 may be applied to semiconductor devices with fin-type architecture.

In some embodiments, the semiconductor structure (e.g., 100, 200, 400, 600, 700 or 800) may include a substrate (e.g., SUB1, SUB2 or SUB3), a gate layer (e.g., GL1, GL2 or GL3), and a plurality of dummy gate layers (e.g., DGL1, DGL2, DGL4, DGL6, DGL7 or DGL8). The substrate may include an active region (e.g., AA1, AA2 or AA3) and a first source/drain region (e.g., one of the drain and source region DR1 and SR1, or the source/drain region S/D), a second source/drain region (e.g., another one of the drain and source region DR1 and SR1, or the source/drain region S/D), and a plurality of lightly doped regions (e.g., LDD1, LDD2 or LDD3) that are disposed in the active region. The gate layer may be disposed over the active region, wherein the first source/drain region and the second source/drain region may be configured at opposite sides of the gate layer along a first direction (e.g., D1), and the plurality of lightly doped regions may be configured between the gate layer and the first source/drain region, and between the gate layer and the second source/drain region, respectively. The plurality of dummy gate layers may be disposed respectively over the plurality of lightly doped regions of the substrate and may be electrically connected to the gate layer.

In some embodiments, the plurality of dummy gate layers (e.g., DGL1, DGL2, DGL4, DGL6, DGL7 or DGL8) may be in direct contact with the gate layer (e.g., GL1, GL2 or GL3). In some embodiments, each dummy gate layer (e.g., DGL1, DGL2, DGL4, DGL7 or DGL8) may include at least one first portion (e.g., LP1, LP2 or LP4) extending in the first direction (e.g., D1) and at least one second portion (e.g., VP1, VP2 or VP4) extending in a second direction (e.g., D2) different from the first direction. The second portion may extend across over the active region and may be in contact with the gate layer through the first portion.

In some embodiments, each dummy gate layer (e.g., DGL1, DGL2, DGL7 or DGL8) may include a plurality of first portions (e.g., LP1 or LP2) disposed at opposite ends of the second portion (e.g., VP1 or VP2) in the second direction (e.g., D2). In some embodiments, each dummy gate layer (e.g., DGL2) may include a plurality of second portions (e.g., VP2) arranged in the first direction (e.g., D1).

In some embodiments, the semiconductor structure (e.g., 100, 200, 300, 400, 500, 600, 700 or 800) may include a substrate (e.g., SUB1, SUB2 or SUB3), a gate structure, and a dummy gate structure. The substrate may include an active region (e.g., AA1, AA2 or AA3) and a source region (e.g., SR1 or S/D), a drain region (e.g., DR1 or S/D), and at least one lightly doped region (e.g., LDD1, LDD2 or LDD3) that are disposed in the active region, wherein the lightly doped region may be disposed between the source region and the drain region in the first direction (e.g., D1). The gate structure may be disposed on the active region and may include a gate layer (e.g., GL1, GL2 or GL3) and a gate insulation layer (e.g., GI1, GI2 or GI3) between the gate layer and the substrate, wherein the source region and the drain region may be configured at opposite sides of the gate layer in the first direction, and the lightly doped region is configured between the gate layer and the drain region. The dummy gate structure may be disposed on the lightly doped region and may include a dummy gate layer (e.g., DGL1, DGL2, DGL3, DGL4, DGL5, DGL6, DGL7 or DGL8) and a dummy gate insulation layer (e.g., DGI1, DGI2 or DGI3) between the dummy gate layer and the substrate, wherein the dummy gate layer is electrically connected to the gate layer.

In this embodiment, the semiconductor structure may include a dielectric layer (e.g., ILD1), a drain conductive contact (e.g., DCT1 or S/D_CT), and a wiring layer (e.g., ML1). The dielectric layer may be disposed on the substrate (e.g., SUB1) and may cover the gate structure and the dummy gate structure. The drain conductive contact may be buried in the dielectric layer and may be electrically connected to the drain region, wherein the dummy gate structure may be disposed between the gate structure and the drain conductive contact. The wiring layer may be disposed on the dielectric layer and may be electrically connected to the gate layer, wherein the dummy gate layer may be directly electrically connected to the gate layer or may be electrically connected to the gate layer through the wiring layer.

In summary, in the semiconductor structures of the above embodiments, the dummy gate layer is configured to be over a lightly doped region and electrically connected to the gate layer, so that the impact on the breakdown voltage can be reduced while the doping concentration of the lightly doped region is increased, and therefore the high-voltage semiconductor component including the semiconductor structure can have desired driving voltage and breakdown voltage at the same time.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate comprising an active region and a source region, a drain region, and at least one lightly doped region that are disposed in the active region;
a gate layer disposed over the active region, wherein the source region and the drain region are configured at opposite sides of the gate layer in a first direction, and the lightly doped region is configured between the gate layer and the drain region; and
a dummy gate layer disposed over the lightly doped region and electrically connected to the gate layer.

2. The semiconductor structure according to claim 1, wherein the dummy gate layer is directly in contact with the gate layer.

3. The semiconductor structure according to claim 2, wherein the dummy gate layer comprises at least one first portion extending in the first direction and at least one second portion extending in a second direction different from the first direction, and the second portion crosses above the active region and is in contact with the gate layer through the first portion.

4. The semiconductor structure according to claim 3, wherein the first portion is disposed outside the active region.

5. The semiconductor structure according to claim 3, wherein the dummy gate layer comprises a plurality of first portions respectively disposed at opposite ends of the second portion in the second direction.

6. The semiconductor structure according to claim 3, wherein the dummy gate layer comprises a plurality of second portions arranged in the first direction.

7. The semiconductor structure according to claim 1, further comprising:
a wiring layer disposed over the gate layer, and the dummy gate layer is electrically connected to the gate layer through the wiring layer.

8. The semiconductor structure according to claim 7, wherein a top surface of the dummy gate layer is directly in contact with the wiring layer.

9. The semiconductor structure according to claim 8, further comprising:
a conductive contact disposed on the dummy gate layer and electrically connecting the dummy gate layer to the wiring layer.

10. The semiconductor structure according to claim 7, wherein the dummy gate layer is spaced apart from the gate layer in the first direction.

11. The semiconductor structure according to claim 1, further comprising:
a drain conductive contact disposed on the drain region,
wherein the dummy gate layer is disposed between the gate layer and the drain conductive contact.

12. The semiconductor structure according to claim 1, wherein the substrate comprises a trench where the active region is formed therein, each of the gate layer and the dummy gate layer comprises a portion covering a bottom surface and a sidewall of the trench, and
the lightly doped region comprises a side portion formed in the sidewall of the trench and a bottom portion formed in the bottom surface of the trench.

13. The semiconductor structure according to claim 1, wherein the substrate comprises an active fin, protruding from a top surface of the substrate, where the active region is formed therein, and each of the gate layer and the dummy gate layer comprises a portion covering a top surface and sidewalls of the active fin, and
the lightly doped region is formed in the active fin.

14. A semiconductor structure, comprising:
a substrate comprising an active region and a first source/drain region, a second source/drain region, and a plurality of lightly doped regions that are disposed in the active region;
a gate layer disposed over the active region, wherein the first source/drain region and the second source/drain region are configured at opposite sides of the gate layer in a first direction, and the plurality of lightly doped regions are respectively configured between the gate layer and the first source/drain region and between the gate layer and the second source/drain region; and
a plurality of dummy gate layers respectively disposed over the plurality of lightly doped regions of the substrate and electrically connected to the gate layer.

15. The semiconductor structure according to claim 14, wherein the plurality of dummy gate layers are directly in contact with the gate layer.

16. The semiconductor structure according to claim 15, wherein each of the dummy gate layers comprises at least one first portion extending in the first direction and at least one second portion extending in a second direction different from the first direction, the second portion crosses above the active region and is in contact with the gate layer through the first portion.

17. The semiconductor structure according to claim 16, wherein each of the dummy gate layers comprises a plurality of first portions respectively disposed at opposite ends of the second portion in the second direction.

18. The semiconductor structure according to claim 16, wherein each of the dummy gate layers comprises a plurality of second portions arranged in the first direction.

19. A semiconductor structure, comprising:
a substrate comprising an active region and a source region, a drain region, and at least one lightly doped region that are disposed in the active region, wherein the lightly doped region is disposed between the source region and the drain region in a first direction;
a gate structure disposed on the active region and comprising a gate layer and a gate insulation layer between the gate layer and the substrate, wherein the source region and the drain region are configured at opposite sides of the gate layer in the first direction, and the lightly doped region is configured between the gate layer and the drain region; and
a dummy gate structure disposed on the lightly doped region and comprising a dummy gate layer and a dummy gate insulation layer between the dummy gate layer and the substrate, wherein the dummy gate layer is electrically connected to the gate layer.

20. The semiconductor structure according to claim 19, further comprising:
a dielectric layer disposed on the substrate and covering the gate structure and the dummy gate structure;
a drain conductive contact embedded in the dielectric layer and electrically connected to the drain region, wherein the dummy gate structure is disposed between the gate structure and the drain conductive contact; and
a wiring layer disposed on the dielectric layer and electrically connected to the gate layer,
wherein the dummy gate layer is directly electrically connected to the gate layer or is electrically connected to the gate layer through the wiring layer.
